(19) United States
(12) Patent Application Publication
(10) Pub. No.: US 2016/0020787 A1
(43) Pub. Date: Jan. 21, 2016

(54) DECODING APPARATUS, DECODING METHOD AND NON-TRANSITORY COMPUTER-READABLE RECORDING MEDIUM CONTAINING A DECODING PROGRAM

(71) Applicant: Kabushiki Kaisha Toshiba, Minato-ku (JP)

(72) Inventors: Tatsuyuki ISHIKAWA, Yokohama (JP); Kazuhiro ICHIKAWA, Yamato (JP); Toshihiko KITAZUME, Kawasaki (JP); Kenji SAKAUE, Yokohama (JP); Kouji SAITOU, Shinagawa (JP)

(73) Assignee: Kabushiki Kaisha Toshiba, Minato-ku (JP)

(21) Appl. No.: 14/531,039

(22) Filed: Nov. 3, 2014

Related U.S. Application Data
(60) Provisional application No. 62/026,108, filed on Jul. 18, 2014.

(51) Int. Cl. H03M 13/11

(52) U.S. Cl. CPC H03M 13/1134

(57) ABSTRACT

According to one embodiment, a parallel processor performs the row processes in parallel in a LDPC decode while performing the column processes in parallel in the LDPC decode, and a control circuit alternately repeats the parallel processes of the row process and the parallel processes of the column process as many times as the number of rows and columns in a check matrix and divides the parallel rows for the row process when the LDPC decode is started.

### CROSS-REFERENCE TO RELATED APPLICATIONS

This application is based upon and claims the benefit of priority from Provisional Patent Application No. 62/026108, filed on Jul. 18, 2014; the entire contents of which are incorporated herein by reference.

### FIELD

Embodiments described herein relate generally to a decoding apparatus, a decoding method, and a non-transitory computer-readable recording medium storing a decoding program.

### BACKGROUND

A low-density parity-check (LDPC) code can achieve a rate extremely close to the Shannon limit that is the theoretical upper limit on the information transmission rate, and is the most efficient code in error-correcting codes.

### BRIEF DESCRIPTION OF THE DRAWINGS

FIG. 1 is a schematic block diagram of the configuration of a memory system to which an LDPC decoding apparatus according to a first embodiment is applied;

FIG. 2 is a schematic block diagram of the configuration of the LDPC decoding apparatus according to the first embodiment;

FIG. 3 is a diagram of an exemplary check matrix used in the LDPC decoding apparatus in FIG. 2;

FIG. 4 is a diagram of a row processing method and column processing method in the LDPC decoding apparatus in FIG. 2;

FIG. 5 is a timing diagram describing the increase and decrease in the current consumed in the LDPC decoding process in the LDPC decoding apparatus in FIG. 2;

FIG. 6 is a flowchart of the LDPC decoding processing method in the LDPC decoding apparatus in FIG. 2;

FIG. 7 is a schematic block diagram of the configuration of an LDPC decoding apparatus in a second embodiment; and

FIG. 8 is a block diagram of an exemplary hardware configuration of an LDPC decoding apparatus in a third embodiment.

### DETAILED DESCRIPTION

In general, according to one embodiment, a parallel processor and a control circuit are provided. The parallel processor performs the row processes in parallel in an LDPC decode while performing the column processes in parallel in the LDPC decode. The control circuit divides the parallel rows for the row process when the LDPC decode is started.

The decoding apparatus according to each of the embodiments will be described in detail with reference to the appended drawings. Note that the present invention is not limited to the embodiments.

### First Embodiment

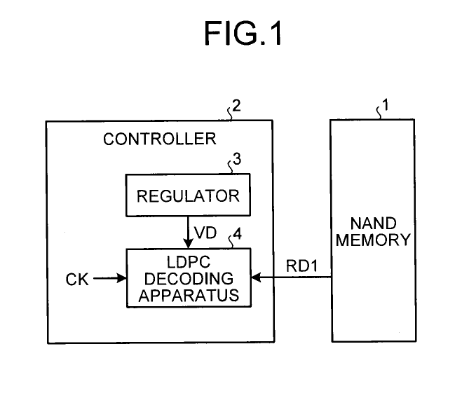

FIG. 1 is a schematic block diagram of the configuration of a memory system to which an LDPC decoding apparatus according to a first embodiment is applied.

In FIG. 1, the memory system is provided with a NAND memory 1 and a controller 2. The controller 2 can control the drive of the NAND memory 1. The control of the drive of the NAND memory 1 can include the control of reading and writing with the NAND memory 1, the block selection, the error correction, and the wear leveling. The NAND memory 1 and the controller 2 can be installed on a memory card such as an SD card, can be installed on a MultiMedia Card such as an eMMC™, can be installed on an external storage device such as a Solid State Drive (SSD), or can be installed on a memory module in compliance with the Universal Flash Storage (UFS) standard.

The controller 2 is provided with an LDPC decoding apparatus 4 configured to perform an LDPC decode, and a regulator 3 configured to supply a voltages VD to the LDPC decoding apparatus 4. The LDPC decoding apparatus 4 can operate at a clock CK that has a single clock frequency. In that case, the LDPC decoding apparatus 4 can perform the row processes in parallel in an LDPC decode while performing the column processes in parallel in the LDPC decode.

When read data RD1 read from the NAND memory 1 is input to the controller 2, the LDPC decoding apparatus 4 performs an LDPC decode. In the LDPC decode, the parallel processes of the row process and the parallel processes of the column process are alternately repeated as many times as the number of rows and columns in the check matrix. At that time, the number of the parallel rows for the first parallel row process is divided when the LDPC decode is started and the divided number of the parallel rows is returned to the original number for the second and subsequent parallel row processes.

The division of the number of the parallel rows for the first parallel row process when the LDPC decode is started can slow the increase in the current consumption when the LDPC decode is started. This can suppress the voltage drop when the LDPC decode is started while suppressing the increase or enlargement in performance of the regulator 3. This can prevent an error operation in the LDPC decode. The return of the divided number of the parallel rows to the original number for the second and subsequent parallel row processes can increase the number of parallel rows for each of the second and subsequent parallel row processes more in comparison with the first process. This can suppress the increase in time for the LDPC decoding process. In order to slow the increase in the current consumption when the LDPC decode is started, it is necessary only to switch the number of parallel rows for a parallel row process, and it is not necessary to switch the clock frequency of the clock CK. This can stabilize the LDPC decoding process while suppressing the increase in waiting time in the LDPC decoding process.

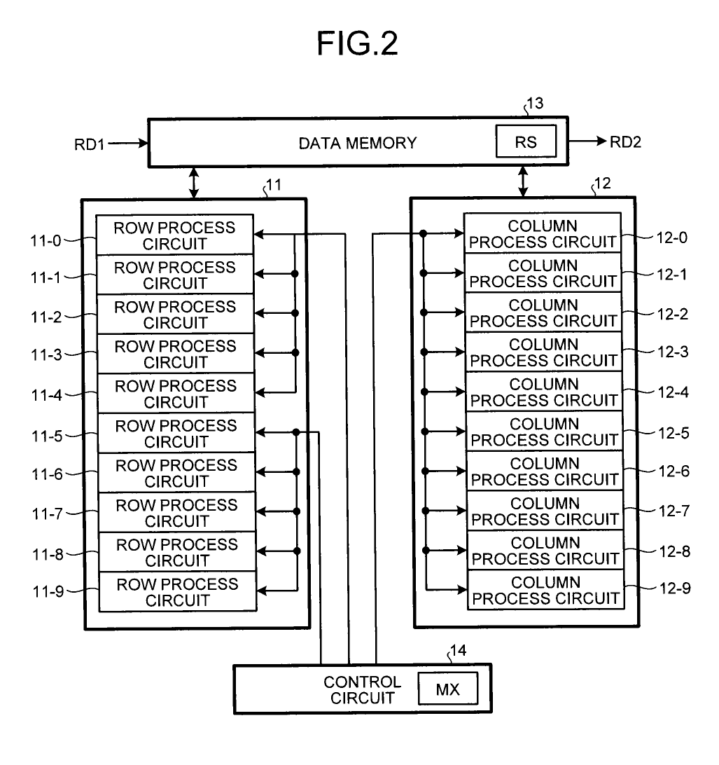

FIG. 2 is a schematic block diagram of the configuration of the LDPC decoding apparatus according to the first embodiment. Note that FIG. 2 illustrates an example in which the number of parallel rows in a parallel row process is ten and the number of parallel columns in a parallel column process is ten. Furthermore, FIG. 2 illustrates an example in which the number of parallel rows in a parallel row process can be divided into half.

In FIG. 2, the LDPC decoding apparatus 4 is provided with a parallel row processor 11, a parallel column processor 12, a control circuit 14, and a data memory 13. The parallel row processor 11 performs the row processes in parallel in the LDPC decode. The parallel column processor 12 performs the column processes in parallel in the LDPC decode. The control circuit 14 alternately repeats the parallel processes of the row process and the parallel processes of the column process as many times as the number of rows and columns in a check matrix MX. The control circuit 14 divides the number of the parallel rows for a parallel row process when the LDPC decode is started. The read data RD1 read from the NAND memory 1 is input to the data memory 13. The parallel row processor 11 is provided with row process circuits 11-0 to 11-9 configured to perform the row processes in the LDPC decode. The parallel column processor 12 is provided with column process circuits 12-0 to 12-9 configured to perform the column processes in the LDPC decode. The row process circuits 11-0 to 11-4 are connected to the control circuit 14 in parallel. The row process circuits 11-5 to 11-9 are connected to the control circuit 14 in parallel. The column process circuits 12-0 to 12-9 are connected to the control circuit 14 in parallel.

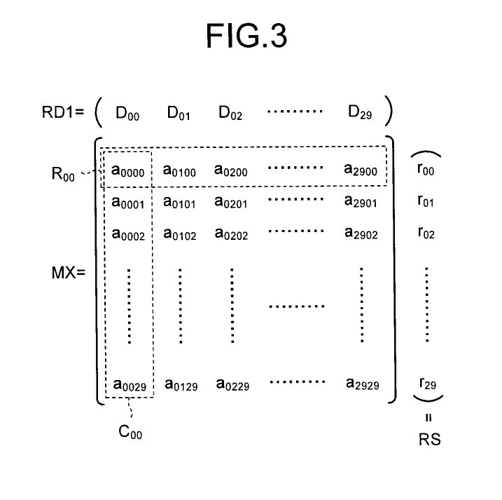

FIG. 3 is a diagram of an exemplary check matrix used in the LDPC decoding apparatus in FIG. 2. Note that FIG. 3 illustrates a check matrix with 30 rows×30 columns as an example.

In FIG. 3, the check matrix MX is provided with elements a₀₀₀₀ to a₂₉₂₉ as 30 rows×30 columns. Note that a value zero or one can be set on each of the elements a₀₀₀₀ to a₂₉₂₉. The check matrix MX can be stored in the control circuit 14 in FIG. 2. In that case, for example, the elements ₐ₀₀₀₀ to a₂₉₀₀ can be included in a first row R₀₀ of the check matrix MX, and the elements a₀₀₀₀ to a₀₀₂₉ can be included in a first column C₀₀ of the check matrix MX. When a decoding process is performed using the check matrix MX, D₀₀ to D₂₉ are input as the read data RD1 to the data memory 13.

In that case, the row process circuits 11-0 to 11-9 can calculate probability values RS by processing rows in the check matrix MX in parallel. The probability values RS can provide probabilities r₀₀ to r₂₉ that the read data D₀₀ to D₂₉ are zero or one. The probability values RS can be stored in the data memory 13 in FIG. 2. The column process circuits 12-0 to 12-9 can process the probability values RS of the rows on which one is set in the check matrix MX, respectively.

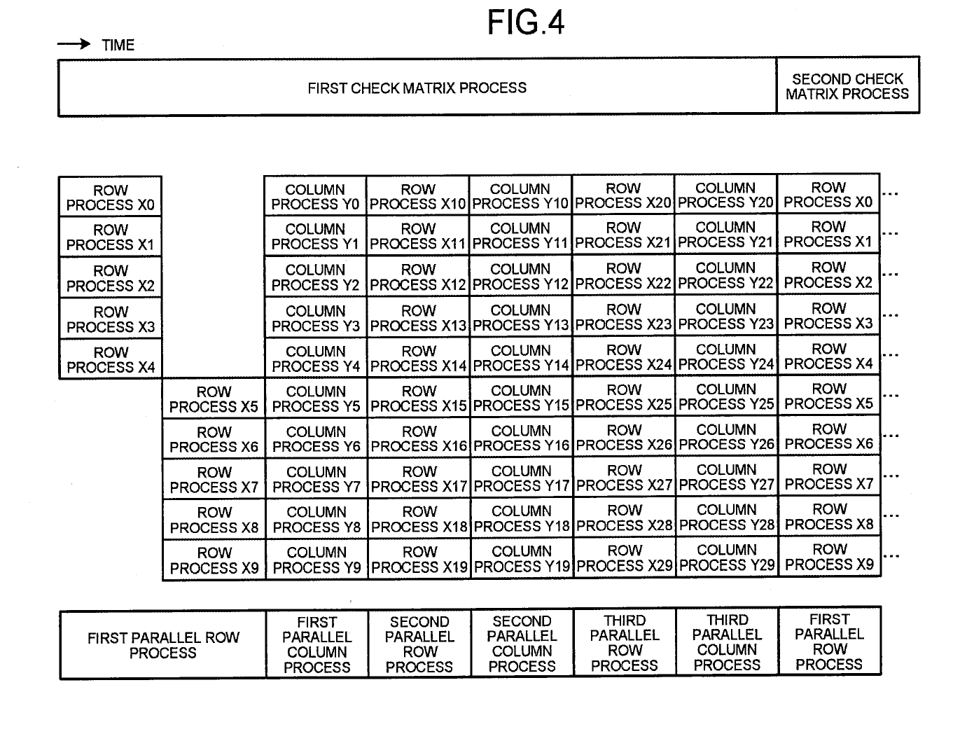

FIG. 4 is a diagram of the row processing method and column processing method in the LDPC decoding apparatus in FIG. 2.

In FIG. 4, when an LDPC decoding process is started, a check matrix process using the check matrix MX is performed. In that case, the check matrix MX in FIG. 3 has 30 rows×30 columns while the row process circuits 11-0 to 11-9 have 10 rows, and the column process circuits 12-0 to 12-9 have 10 columns. Thus, in a check matrix process for one time, a parallel row process for 10 rows and a parallel column process for 10 columns are alternately repeated three times. This can process 30 rows×30 columns.

In that case, in a first parallel row process of a first check matrix process, the row process circuits 11-0 to 11-4 perform row processes X0 to X4 for the zeroth to fourth rows of the check matrix MX in parallel. After that, the row process circuits 11-5 to 11-9 perform the row processes X5 to X9 for the fifth to ninth rows in parallel. At that time, the probability values RS of the ten rows are stored in the data memory 13. Next, in a first parallel column process, the column process circuits 12-0 to 12-9 perform the column processes Y0 to Y9 for the zeroth to ninth columns of the check matrix MX based on the probability values RS calculated in the first parallel row process. Next, in a second parallel row process, the row process circuits 11-0 to 11-9 perform the row processes X10 to X19 for the tenth to nineteenth rows of the check matrix MX in parallel. At that time, the probability values RS of the ten rows are stored in the data memory 13. Next, in a second parallel column process, the column process circuits 12-0 to 12-9 perform the column processes Y10 to Y19 for the tenth to nineteenth columns of the check matrix MX in parallel based on the probability values RS calculated in the first parallel row process and the second parallel row process. Next, in a third parallel row process, the row process circuits 11-0 to 11-9 perform the row processes X20 to X29 for the twentieth to twenty ninth rows of the check matrix MX in parallel. At that time, the probability values RS of the ten rows are stored in the data memory 13. Next, in a third parallel column process, the column process circuits 12-0 to 12-9 perform the column processes Y20 to Y29 for the twentieth to twenty ninth columns of the check matrix MX in parallel based on the probability values RS calculated in the first parallel row process to the third parallel row process. After the error in the read data RD1 is corrected in the first check matrix process, the corrected data is stored in the data memory 13. Then, the read data of which error has been corrected in the first check matrix process is checked in a parity check. If the read data does not pass the parity check, a second check matrix process is performed. The check matrix process can be repeated until the read data passes the parity check, or the number of the parity checks reaches a predetermined number of times. Error-corrected read data RD2 finally obtained from the LDPC decode is output through the data memory 13.

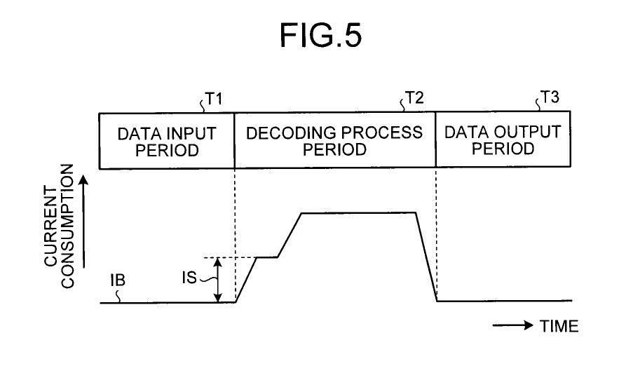

FIG. 5 is a timing diagram describing the increase and decrease in the current consumed in the LDPC decoding process in the LDPC decoding apparatus in FIG. 2.

In FIG. 5, on the assumption that the current consumption during a data input period T1 and a data output period T3 is IB, the current consumption is increased by IS when only the row process circuits 11-0 to 11-4 operate at the start of the decoding process period T2. This can slow the increase in the current consumption in comparison with the case in which the row process circuits 11-0 to 11-9 operate at the start of the decoding process period T2.

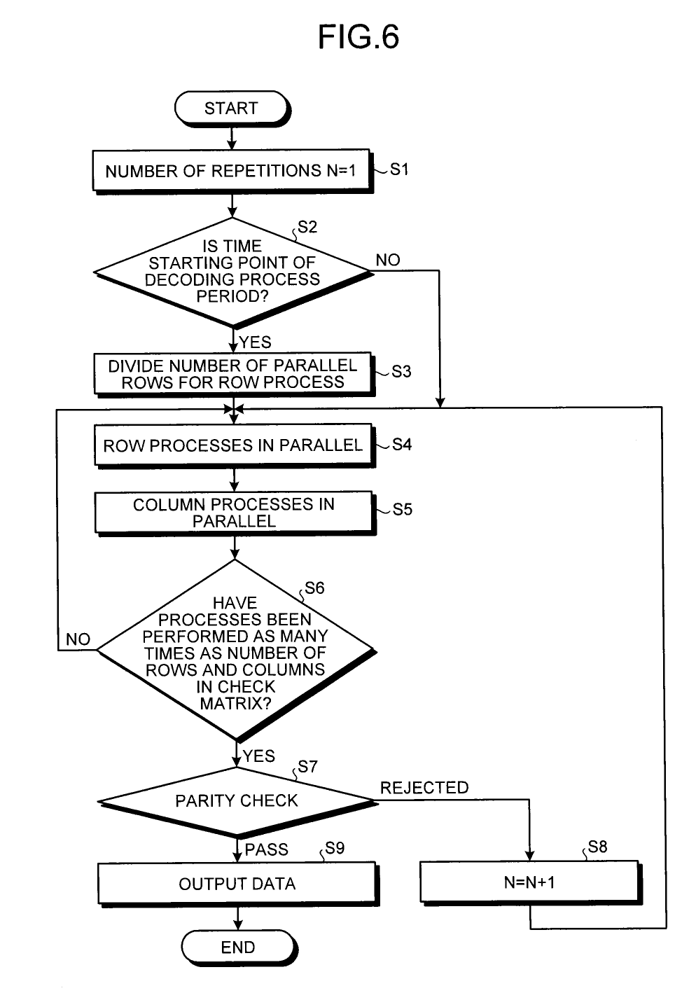

FIG. 6 is a flowchart of the LDPC decoding processing method in the LDPC decoding apparatus in FIG. 2.

In FIG. 6, when an LDPC decoding process is started, the number of iterations N of the check matrix process is set at one (step S1). Next, it is determined whether the time is the starting point of the decoding process period T2 (step S2). When the time is the starting point of the decoding process period T2, the number of the parallel rows for a row process is divided (step S3). Processing each of the divided number of the parallel rows in the row process in parallel can calculate the probability value RS for each row (step S4). Next, the column processes are performed in parallel based on the probability values RS calculated in the row processes and the error correction of data for decoding is performed (step S5). Next, it is determined whether the row processes and column processes are performed as many times as the number of rows and columns in the check matrix MX (step S6). When the row processes and column processes are performed as many times as the number of rows and columns in the check matrix MX, the error-corrected data is checked in a parity check (step S7). When passing the parity check, the error-corrected data is output (step S9). On the other hand, when the error-corrected data is rejected in the parity check in step S7, the number of iterations N of the check matrix process is incremented only by one (step S8) and the process goes back to step S4. The processes in steps S4 to S8 are repeated until the data passes the parity check. On the other hand, when the row processes and column processes are not performed as many times as the number of rows and columns in the check matrix MX in step S6, the process goes back to step S1. The processes in steps S4 to S6 are repeated until the row processes and column processes are performed as many times as the number of rows and columns in the check matrix MX. On the other hand, when the time is not the starting point of the decoding process period T2 in step S2, the process in step S3 is skipped and the processes in and after step S4 are performed.

### Second Embodiment

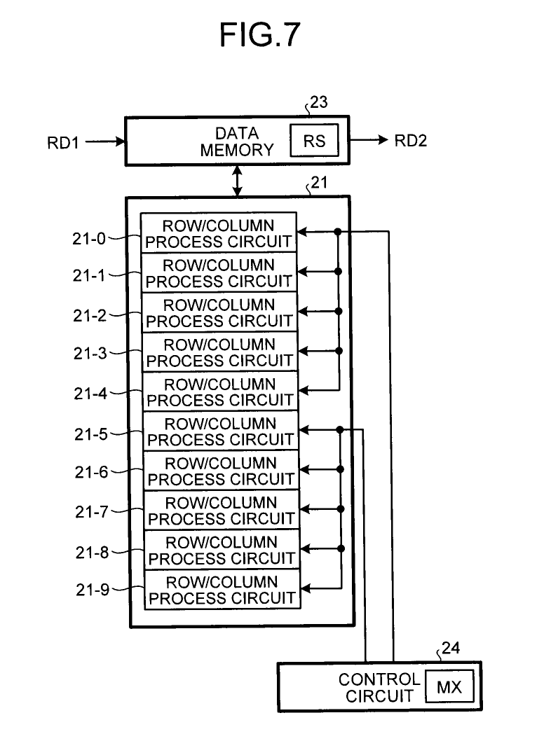

FIG. 7 is a schematic block diagram of the configuration of an LDPC decoding apparatus in a second embodiment. Note that FIG. 7 illustrates an example in which the numbers of parallel rows and parallel columns for a row/column process are each ten.

In FIG. 7, the LDPC decoding apparatus is provided with a parallel row/column processor 21, a control circuit 24, and a data memory 23. The parallel row/column processor 21 switches and performs row processes and column processes in parallel in an LDPC decode. Note that the parallel row/column processor 21 includes a common computing unit that can be shared for the row process and the column process. The control circuit 24 switches and alternately repeats the parallel processes of a row process and the parallel processes of a column process as many times as the number of rows and columns in a check matrix MX. The control circuit 24 divides the number of the parallel rows for the row process when the LDPC decode is started. Read data RD1 read from a NAND memory 1 is input to the data memory 23. The parallel row/column processor 21 is provided with row/column process circuits 21-0 to 21-9 configured to switch and perform the row processes and column processes in an LDPC decode. The row/column process circuits 21-0 to 21-4 are connected to the control circuit 24 in parallel. The row/column process circuits 21-5 to 21-9 are connected to the control circuit 24 in parallel.

Then, in the first parallel row process of the first check matrix process in FIG. 4, the row/column process circuits 21-0 to 21-4 perform the row processes X0 to X4 for the zeroth to fourth rows of the check matrix MX in parallel. After that, the row/column process circuits 21-5 to 21-9 perform the row processes X5 to X9 for the fifth to ninth rows in parallel. At that time, the probability values RS of the ten rows are stored in the data memory 23. Next, in the first parallel column process, the row/column process circuits 21-0 to 21-9 perform the column processes Y0 to Y9 for the zeroth to ninth columns of the check matrix MX in parallel based on the probability values RS calculated in the first parallel row process. Next, in the second parallel row process, the row/column process circuits 21-0 to 21-9 perform the row processes X10 to X19 for the tenth to nineteenth rows of the check matrix MX in parallel. At that time, the probability values RS of the ten rows are stored in the data memory 23. Next, the second parallel column process, the row/column process circuits 21-0 to 21-9 perform the column processes Y10 to Y19 for the tenth to nineteenth columns of the check matrix MX in parallel based on the probability values RS calculated in the first parallel row process and the second parallel row process. Next, in the third parallel row process, the row/column process circuits 21-0 to 21-9 perform the row processes X20 to X29 for the twentieth to twenty ninth rows of the check matrix MX in parallel. At that time, the probability values RS of the ten rows are stored in the data memory 23. Next, in the third parallel column process, the row/column process circuits 21-0 to 21-9 perform the column processes Y20 to Y29 for the twentieth to twenty ninth columns in the check matrix MX in parallel based on the probability values RS calculated in the first parallel row process to the third parallel row process. In the first check matrix process, the error in the read data RD1 is corrected and the data is stored in the data memory 23. Then, the read data of which error has been corrected in the first check matrix process is checked in a parity check. If the read data does not pass the parity check, the second check matrix process is performed. The check matrix process can be repeated until the read data passes the parity check, or the number of the parity checks reaches a predetermined number of times. Error-corrected read data RD2 finally obtained from the LDPC decode is output through the data memory 23.

### Third Embodiment

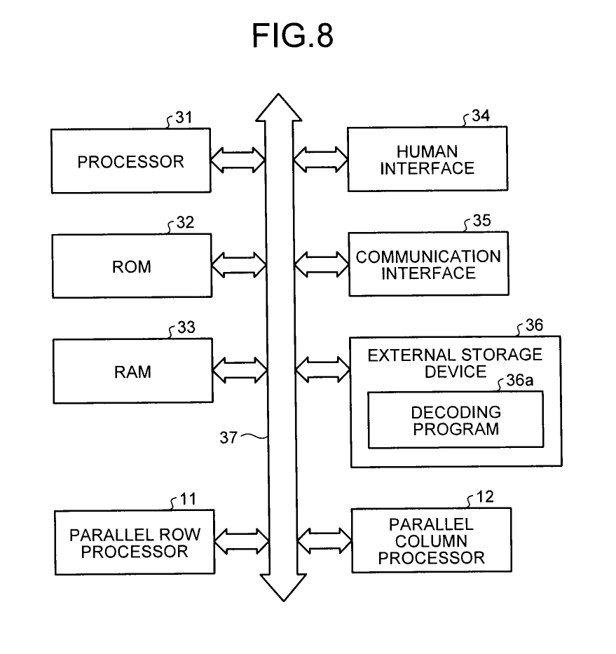

FIG. 8 is a block diagram of an exemplary hardware configuration of an LDPC decoding apparatus in a third embodiment.

In FIG. 8, the LDPC decoding apparatus can be provided with a processor 31 including a CPU or the like, a ROM 32 configured to store fixed data, a RAM 33 configured to provide a work area or the like to the processor 31, a human interface 34 configured to mediate between a person and the computer, a communication interface 35 configured to provide a communication unit with the outside, an external storage device 36 configured to store a program or various types of data for operating the processor 31, a parallel row processor 11, and a parallel column processor 12. The processor 31, the ROM 32, the RAM 33, the human interface 34, the communication interface 35, the external storage device 36, the parallel row processor 11, and the parallel column processor 12 are connected to each other through a bus 37. Instead of the parallel row processor 11 and the parallel column processor 12, a parallel row/column processor 21 can be provided.

Note that, for example, a magnetic disk such as a hard disk, an optical disk such as a DVD, or a portable semiconductor storage device such as a USB memory or a memory card can be used as the external storage device 36. For example, a keyboard, a mouse, or a touch panel can be used as the input interface of the human interface 34, and a display or a printer can be used as the output interface of the human interface 34. For example, a LAN card, a modem, or a router configured to connect the computer to the Internet, or a LAN can be used as the communication interface 35. In that case, a decoding program 36a that executes an LDPC decode is installed on the external storage device 36.

When the decoding program 36a is executed with the processor 31, the parallel process of a row process and the parallel process of a column process are alternately repeated as many times as the number of rows and columns in the check matrix. This performs an LDPC decode. At that time, the number of the parallel rows for a row process is divided when the LDPC decode is started.

Note that the decoding program 36a executed with the processor 31 can be stored in the external storage device 36 so as to be read in the RAM 33 when the program is executed. Alternatively, the decoding program 36a can be stored in the ROM 32 in advance. Alternatively, the decoding program 36a can be obtained through the communication interface 35. Furthermore, the decoding program 36a can be executed with a stand-alone computer or can be executed with a cloud computer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A decoding apparatus comprising:
a parallel processor configured to perform row processes in parallel in a Low-Density Parity-check Code (LDPC) decode while performing column processes in parallel in the LDPC decode; and
a control circuit configured to divide the number of parallel rows for the row process when the LDPC decode is started.

2. The decoding apparatus according to claim 1, wherein the parallel processor includes a parallel row processor configured to perform the row processes in parallel in the LDPC decode, and
a parallel column processor configured to perform the column processes in parallel in the LDPC decode.

3. The decoding apparatus according to claim 1, wherein the parallel processor includes a parallel row/column processor configured to switch and perform the parallel processes of a row process in the LDPC decode and the parallel processes of a column process in the LDPC decode.

4. The decoding apparatus according to claim 3, wherein the parallel row/column processor includes a common computing unit shared for the row process and the column process.

5. The decoding apparatus according to claim 1, wherein the control circuit alternately repeats the parallel processes of the row process and the parallel processes of the column process as many times as the number of rows and columns in a check matrix.

6. The decoding apparatus according to claim 5, wherein the control circuit divides the number of parallel rows for a first parallel row process into half in a first check matrix process when the LDPC decode is started.

7. The decoding apparatus according to claim 6, wherein the control circuit divides the number of parallel rows for the first parallel row process into half in the first check matrix process and returns the divided number of the parallel rows to an original number for a second parallel row process in the first check matrix process.

8. The decoding apparatus according to claim 7, wherein the control circuit divides the number of parallel rows for the first parallel row process into half in the first check matrix process and does not divide the number of columns for a first parallel column process in the first check matrix process.

9. The decoding apparatus according to claim 8, performing the first parallel column process based on probability values that determine zero or one and have been found in the divided first parallel row process after the completion of the divided first parallel row process.

10. The decoding apparatus according to claim 1, wherein the parallel processor operates at a single clock frequency.

11. The decoding apparatus according to claim 10, further comprising a regulator configured to supply a voltage to the parallel processor.

12. The decoding apparatus according to claim 11, being installed on a controller controlling a NAND memory.

13. The decoding apparatus according to claim 12, further comprising a data memory to which data to be decoded with the LDPC decode is input.

14. The decoding apparatus according to claim 13, wherein the data to be decoded with the LDPC decode is read data in the NAND memory.

15. A decoding method comprising:
performing row processes in parallel in a Low-Density Parity-check Code (LDPC) decode;
performing column processes in parallel in the LDPC decode; and
dividing the number of parallel rows for the row process when the LDPC decode is started.

16. The decoding method according to claim 15, further comprising alternately repeating the parallel processes of the row process and the parallel processes of the column process as many times as the number of rows and columns in a check matrix.

17. The decoding method according to claim 16, further comprising dividing the number of parallel rows for a first parallel row process into half when the LDPC decode is started, and returning the divided number of the parallel rows to an original number for second and subsequent parallel row processes.

18. A non-transitory computer-readable recording medium that stores a decoding program for causing a computer to execute a process, the process comprising:
performing row processes in parallel in a Low-Density Parity-check Code (LDPC) decode;
performing column processes in parallel in the LDPC decode; and
dividing the number of parallel rows for the row process when the LDPC decode is started.

19. The non-transitory computer-readable recording medium according to claim 18 that stores the decoding program for causing the computer to execute the process, the process further comprising:
alternately repeating the parallel processes of the row process and the parallel processes of the column process as many times as the number of rows and columns in a check matrix.

20. The non-transitory computer-readable recording medium according to claim 19 that stores the decoding program for causing the computer to execute the process, the process further comprising:
dividing the number of parallel rows for the first parallel row process into half when the LDPC decode is started, and returning the divided number of the parallel rows to an original number for second and subsequent parallel row processes.
